(19) United States
(12) Patent Application Publication
(10) Pub. No.: US 2024/0234618 A1
(43) Pub. Date: Jul. 11, 2024

(54) Optoelectronic Semiconductor Structure

(71) Applicant: SENSORTEK TECHNOLOGY CORP., Hsinchu County (TW)

(72) Inventor: Ching-Kuan Chiu, Hsinchu County (TW)

(21) Appl. No.: 18/140,692

(22) Filed: Apr. 28, 2023

Related U.S. Application Data
(60) Provisional application No. 63/363,879, filed on Apr. 29, 2022.

(51) Int. Cl. H01L 31/113

(52) U.S. Cl. CPC H01L 31/1136

(57) ABSTRACT

The present invention provides an optoelectronic semiconductor structure, which comprises a first-type semiconductor substrate, a second-type semiconductor light-receiving region, and a second-type semiconductor conduction region. The first-type semiconductor substrate includes a top surface. The second-type semiconductor conduction region is used to conduct a photocurrent. The second-type semiconductor light-receiving region is located on the periphery of the second-type semiconductor conduction region. The second-type semiconductor conduction region and the second-type semiconductor light-receiving region are spaced by a distance. By dividing into the semiconductor conduction region and the light-receiving region, the effect of reducing the junction capacitance while maintaining the light-receiving capability can be achieved and thus further enhancing the photoelectric conversion efficiency of the optoelectronic semiconductor structure.

### BACKGROUND OF THE INVENTION

The operating principle of optoelectronic semiconductors includes the usage of the photoelectric effect at the p-n junction of semiconductors. When the light is incident to semiconductors with energy greater than the bandgap, the electrons or holes in the valence band absorb the energy of light and are excited to the conduction band. Then, owing to the built-in or external electric field, the electrons or holes will be moved to form a photocurrent.

A current optoelectronic semiconductor structure from the bottom up includes a cathode bottom electrode, an n-type semiconductor substrate, a p-type semiconductor doped region, and an anode top electrode. The top electrode includes an opening as the light-receiving window. A depletion region will be formed at the p-n junction. When the light with sufficient energy is incident to the light-receiving window, the ionization effect as described above will occur and generate electron-hole pairs. The existing electric field will move the electrons to the cathode and the holes to the anode and thus generating a photocurrent. If the intensity of light is stronger, the magnitude of the photocurrent will be larger. Thereby, by calculating the value of the photocurrent by using an analog-to-digital conversion circuit (normally including integrators formed by amplifiers), the intensity of the incident light can be judged. Of course, the conduction type of optoelectronic semiconductors can be opposite to the above description. However, the structure and operations are basically the same.

To better receive the incident light for enhancing the sensitivity of light sensing, the area of the p-n junction is preferably larger in the hope of acquiring larger photocurrents. Unfortunately, a large p-n junction increases the junction capacitance, which will increase the response delay and amplify noise in circuits.

Accordingly, how to reduce the junction capacitance while maintaining the light-receiving capability of optoelectronic semiconductors structures has become a major challenge in the field.

### SUMMARY OF THE INVENTION

A major objective of the present invention is to provide an optoelectronic semiconductor structure, which achieves the effect of reducing the junction capacitance while maintaining the light-receiving capability by dividing into a semiconductor conduction region and a light-receiving region and thus further enhancing the photoelectric conversion efficiency of the optoelectronic semiconductor structure.

A secondary objective of the present invention is to provide an optoelectronic semiconductor structure, which achieves the effect of adjusting the built-in electric field of the substrate using the gate bias by disposing the gate layer on the semiconductor substrate and between the semiconductor conduction region and the light-receiving region. By accelerating electron diffusion, the junction capacitance can be further reduced.

Another secondary objective of the present invention is to provide an optoelectronic semiconductor structure, which achieves the effect of reducing the noises induced by the gate bias by disposing an isolation region between the semiconductor conduction region and the light-receiving region and further generates the channel capacitance for accelerating electron diffusion.

A further secondary objective of the present invention is to provide an optoelectronic semiconductor structure, which achieves the effect of reducing the dark current on the surface by disposing a shelter layer on the light-receiving region and thus further reducing the noise entering the conduction region.

To achieve the above major objective, the present invention provides an optoelectronic semiconductor structure, which comprises a first-type semiconductor substrate, a second-type semiconductor light-receiving region, and a second-type semiconductor conduction region. The first-type semiconductor substrate includes a top surface. The second-type semiconductor conduction region is disposed on the top surface of the first-type semiconductor substrate. The second-type semiconductor conduction region is used to conduct the photocurrent from the second-type semiconductor light-receiving region. The second-type semiconductor light-receiving region is located on the periphery of the second-type semiconductor conduction region. The second-type semiconductor conduction region and the second-type semiconductor light-receiving region are spaced by a distance.

According to an embodiment of the present invention, the second-type semiconductor light-receiving region surrounds or partially surrounds the second-type semiconductor conduction region.

According to an embodiment of the present invention, the first-type semiconductor substrate includes a spacer part. The inner side of the spacer part surrounds or partially surrounds the second-type semiconductor conduction region. The outer side of the spacer part is adjacent to the second-type semiconductor light-receiving region.

To achieve the above secondary objective, according to an embodiment, the optoelectronic semiconductor structure further comprises a bias gate layer covering the top surface of the first-type semiconductor substrate and located between the second-type semiconductor light-receiving region and the second-type semiconductor conduction region.

According to an embodiment of the present invention, a first side of the bias gate layer is disposed on the second-type semiconductor light-receiving region; a second side of the bias gate layer is disposed on the second-type semiconductor conduction region.

To achieve the above secondary objective, according to an embodiment, the optoelectronic semiconductor structure further comprises an isolation layer disposed on the outer side of the second-type semiconductor conduction region and on the top surface of the first-type semiconductor substrate/The isolation layer and the second-type semiconductor light-receiving region are spaced by a distance.

According to an embodiment of the present invention, the isolation layer is a shallow trench isolation (STI) with material selected from the group consisting of silicon nitride (Si3N4), silicon carbide (SiC), and silicon dioxide (SiO2).

According to an embodiment of the present invention, the isolation layer is a first-type semiconductor layer. The concentration of ions implanted into the first-type semiconductor layer (the isolation layer) is higher than the concentration of ions implanted into the first-type semiconductor substrate.

According to an embodiment of the present invention, the second-type semiconductor light-receiving region is disposed on the top surface of the first-type semiconductor substrate.

To achieve the above secondary objective, according to an embodiment, the optoelectronic semiconductor structure further comprises a first-type semiconductor shelter layer disposed on the second-type semiconductor light-receiving region and on the top surface of the first-type semiconductor substrate.

According to an embodiment of the present invention, the first-type semiconductor shelter layer is disposed on the second-type semiconductor light-receiving region facing the bias gate layer.

According to an embodiment of the present invention, the bias gate layer is polysilicon.

According to an embodiment of the present invention, the second-type semiconductor conduction region is coupled to an analog-to-digital conversion circuit.

According to an embodiment of the present invention, the second-type semiconductor light-receiving region is a second-type semiconductor well; and the second-type semiconductor conduction region is a second-type semiconductor with high doping concentration.

According to an embodiment of the present invention, the concentration of ions implanted into the second-type semiconductor conduction region is greater than the concentration of ions implanted into the second-type semiconductor light-receiving region.

According to an embodiment of the present invention, when the first-type semiconductor substrate is a p-type semiconductor, the photocurrent includes the photoelectrons flowing from the second-type semiconductor light-receiving region to the second-type semiconductor conduction region via the first-type semiconductor substrate.

According to an embodiment of the present invention, when the first-type semiconductor substrate is an n-type semiconductor, the photocurrent includes the holes flowing from the second-type semiconductor light-receiving region to the second-type semiconductor conduction region via the first-type semiconductor substrate.

### BRIEF DESCRIPTION OF DRAWINGS

FIG. 1A shows a cross-sectional view of the optoelectronic semiconductor structure according to the first embodiment of the present invention;

FIG. 1B shows a schematic diagram of current flow in the optoelectronic semiconductor structure according to the first embodiment of the present invention;

FIG. 1C shows a band diagram of the optoelectronic semiconductor structure according to the first embodiment of the present invention;

FIG. 1D shows a schematic diagram of another current flow in the optoelectronic semiconductor structure according to the first embodiment of the present invention;

FIG. 2A shows a cross-sectional view of the optoelectronic semiconductor structure according to the second embodiment of the present invention;

FIG. 2B shows a schematic diagram of current flow in the optoelectronic semiconductor structure according to the second embodiment of the present invention;

FIG. 2C shows a band diagram of the optoelectronic semiconductor structure according to the second embodiment of the present invention;

FIG. 3A shows a cross-sectional view of the optoelectronic semiconductor structure according to the third embodiment of the present invention;

FIG. 3B shows a schematic diagram of current flow in the optoelectronic semiconductor structure according to the third embodiment of the present invention;

FIG. 4 shows a cross-sectional view of the optoelectronic semiconductor structure according to the fourth embodiment of the present invention;

FIG. 5A shows a cross-sectional view of the optoelectronic semiconductor structure according to the fifth embodiment of the present invention;

FIG. 5B shows a schematic diagram of current flow in the optoelectronic semiconductor structure according to the fifth embodiment of the present invention;

FIG. 6 shows a cross-sectional view of the optoelectronic semiconductor structure according to the sixth embodiment of the present invention;

FIG. 7 shows a cross-sectional view of the optoelectronic semiconductor structure according to the seventh embodiment of the present invention;

FIG. 8 shows a cross-sectional view of the optoelectronic semiconductor structure according to the eighth embodiment of the present invention;

FIG. 9 shows a top view of the optoelectronic semiconductor structure according to the ninth embodiment of the present invention; and

FIG. 10 shows a schematic diagram of the circuit architecture of the optoelectronic semiconductor structure according to the tenth embodiment of the present invention.

### DETAILED DESCRIPTION OF THE INVENTION

In order to make the structure and characteristics as well as the effectiveness of the present invention to be further understood and recognized, the detailed description of the present invention is provided as follows along with embodiments and accompanying figures.

In current optoelectronic semiconductor structures, to acquire a larger photocurrent, the area of the p-n junction should be increased. Unfortunately, increasing the area directly will increase the junction capacitance and lead to difficulty in circuit design because of increased response delay or noises of amplified circuit.

The present invention separates the conduction region and the light-receiving region of semiconductors for achieving low junction capacitance while maintaining the light-receiving capability. Thereby, the photoelectric conversion efficiency of optoelectronic semiconductor structures can be further increased.

In the following description, various embodiments of the present invention are described using figures for describing the present invention in detail. Nonetheless, the concepts of the present invention can be embodied in various forms. Those embodiments are not used to limit the scope and range of the present invention.

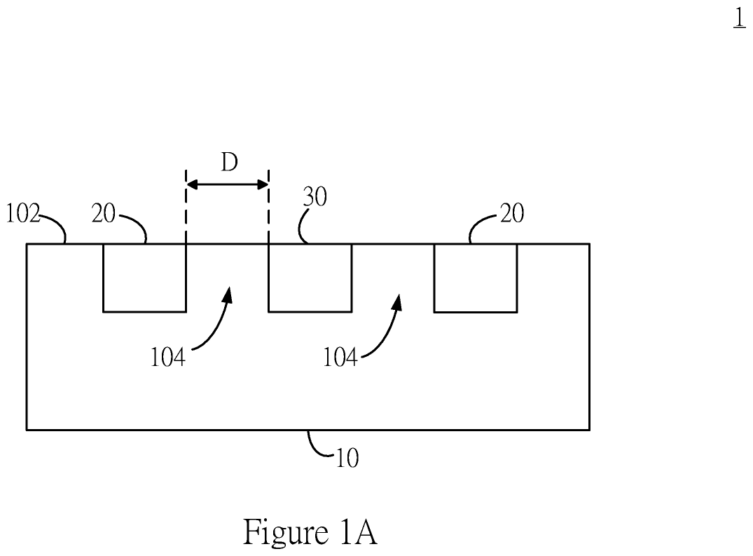

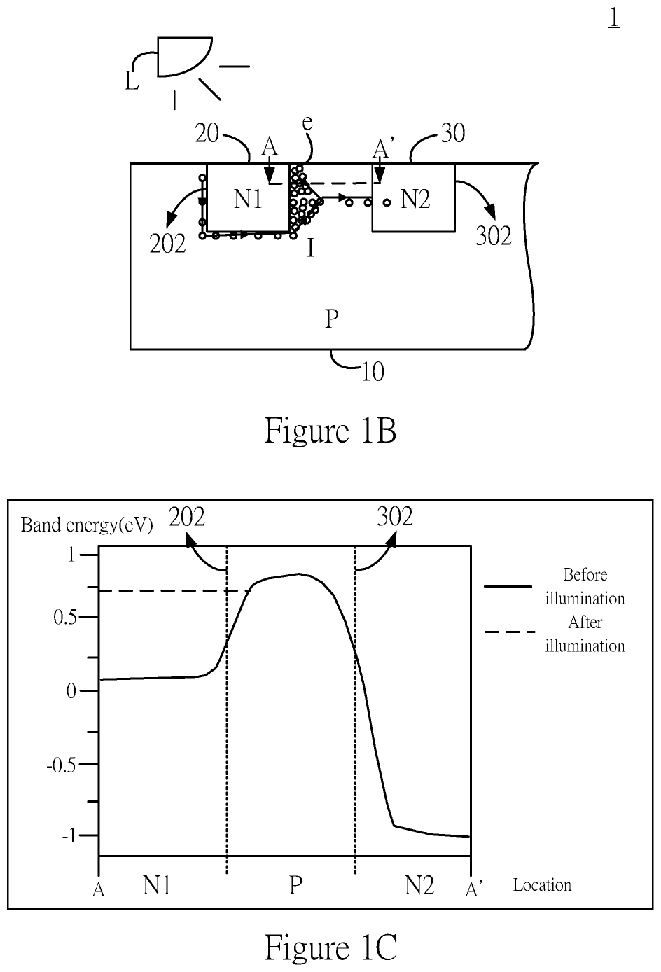

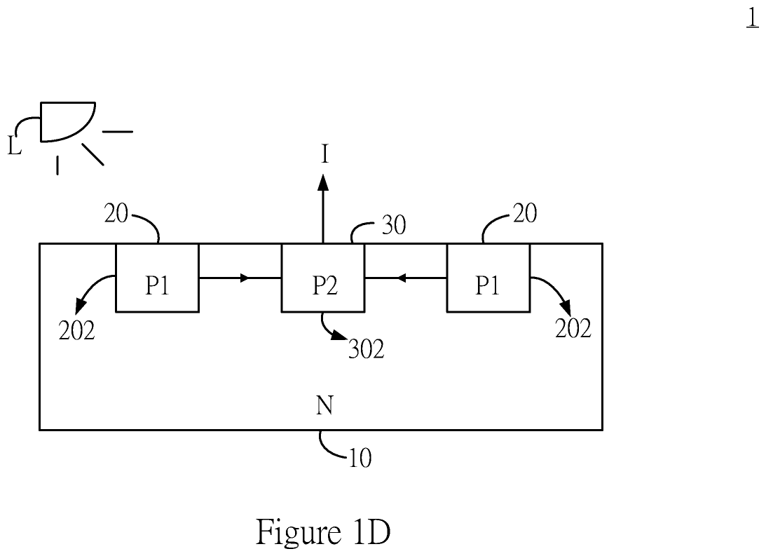

Please refer to FIG. 1A, which shows a cross-sectional view of the optoelectronic semiconductor structure according to the first embodiment of the present invention. The optoelectronic semiconductor structure 1 according to the first embodiment of the present invention comprises a first-type semiconductor substrate 10, a second-type semiconductor light-receiving region 20, and a second-type semiconductor conduction region 30. When the first-type semiconductor is a p-type semiconductor, the second-type semiconductor is an n-type semiconductor. Contrarily, when the first-type semiconductor is an n-type semiconductor, the second-type semiconductor is a p-type semiconductor.

According to the first embodiment, the first-type semiconductor substrate 10 includes a top surface 102. The second-type semiconductor light-receiving region 20 can be generally formed on the top surface 102 of the first-type semiconductor substrate 10 by selective diffusion (for example, using a mask or other lithography technologies). The second-type semiconductor conduction region 30 can also be formed on the top surface 102 of the first-type semiconductor substrate 10 by selective diffusion. The second-type semiconductor light-receiving region 20 receives the incident light (for example, the ambient light). To acquire a larger photocurrent, the p-n junction between the second-type semiconductor light-receiving region 20 and the first-type semiconductor substrate 10 should be as large as possible. Thereby, the area of the second-type semiconductor light-receiving region 20 should be as large as possible. On the contrary, the second-type semiconductor conduction region 30 is coupled to the external circuit (in general, via one or multiple metal layers) so that the photocurrent can be conducted to the external circuit. The p-n junction between the second-type semiconductor conduction region 30 and the first-type semiconductor substrate 10 should be as small as possible so that the junction capacitance contacted by the external circuit (such as an analog-to-digital conversion circuit, normally including integrators formed by amplifiers) can be small. Thereby, the area of the second-type semiconductor conduction region 30 should be as small as possible.

A method to extend the area of the second-type semiconductor light-receiving region 20 is to surround the second-type semiconductor conduction region 30 using the second-type semiconductor light-receiving region 20. Alternatively, at least partially surround the second-type semiconductor conduction region 30 using the second-type semiconductor light-receiving region 20. To elaborate, the first-type semiconductor substrate 10 includes a spacer part 104. The inner side of the spacer part 104 surrounds or partially surrounds the second-type semiconductor conduction region 30. The outer side of the spacer part 104 is adjacent to the second-type semiconductor light-receiving region 20. Thereby, the second-type semiconductor light-receiving region 20 is disposed on the surrounding the second-type semiconductor conduction region 30. While doing layout, it is easy to make the second-type semiconductor light-receiving region 20 have a larger area. The crucial point is that the second-type semiconductor conduction region 30 and the second-type semiconductor light-receiving region 20 are spaced by a distance D. To elaborate, the distance D is the distance between the second-type semiconductor conduction region 30 and the second-type semiconductor light-receiving region 20 in the direction parallel with the top surface 102. If the distance between the second-type semiconductor conduction region 30 and the second-type semiconductor light-receiving region 20 is not fixed, the distance D is the minimum distance therebetween, preferably between 0.5 μm and 5 μm.

The optoelectronic semiconductor structure 1 according to the first embodiment of the present invention is to introduce the distance D between the second-type semiconductor conduction region 30 and the second-type semiconductor light-receiving region 20 to make the area of the p-n junction between the second-type semiconductor light-receiving region 20 and the first-type semiconductor substrate 10 larger. The external circuit is coupled to the second-type semiconductor conduction region 30. The area of the p-n junction between the second-type semiconductor conduction region 30 and the first-type semiconductor substrate 10 is not large. Thereby, the junction capacitance is still controlled within a smaller range. Accordingly, the effect of reducing the junction capacitance while maintaining the light-receiving capability can be achieved.

In the following, the operation principle of the optoelectronic semiconductor structure 1 according to the first embodiment of the present invention will be described. Please refer to FIG. 1B, which shows a schematic diagram of current flow in the optoelectronic semiconductor structure according to the first embodiment of the present invention. For convenience, in FIG. 1B and the several subsequent figures, only a portion of the second-type semiconductor light-receiving region 20 and the first-type semiconductor substrate 10 will be shown. Thereby, the right side of the figures is represented by a curved line. When the first-type semiconductor substrate 10 is a p-type semiconductor P, the second-type semiconductor light-receiving region 20 is an n-type semiconductor N1 (such as an n-type semiconductor well); and the second-type semiconductor conduction region 30 is an n-type semiconductor N2 (such as an n-type high-doping region). Between the second-type semiconductor light-receiving region 20 and the first-type semiconductor substrate 10, there is a p-n junction 202. When a light source L (such as the ambient light) illuminates the optoelectronic semiconductor structure 1, the energy of photons will be absorbed by the carriers in the valence band. If the energy of photons provided by the light source L is greater than the bandgap energy of the p-n junction 202, the energy of photons will excite the carriers in the valence band to the conduction band and generating additional free electrons and holes at the p-n junction 202. The free electrons generated by absorbing the energy of photons are called photoelectrons. When the photoelectrons e generated at the p-n junction 202 by the illumination of the light source L accumulate to surmount the energy barrier of the first-type semiconductor substrate 10, photoelectrons e will be moved from the p-n junction 202 to the second-type semiconductor conduction region 30 via the first-type semiconductor substrate 10, meaning that the accumulated photoelectrons e are sufficient to form a photocurrent I. In practice, holes will be moved in the direction opposite to the direction of photoelectrons. According to the general convention, the photocurrent I is negative. Nonetheless, the negative value does not influence the illustration of the operation of the overall circuit. Hence, the details will not be described. If the light intensity emitted by the light source L is larger, the value of the photocurrent I will be larger accordingly. As described above, the second-type semiconductor conduction region 30 can be coupled to the external circuit for conducting the photocurrent I for the external circuit. The external circuit can judge the light intensity by calculating the value of the photocurrent I. There is another p-n junction 302 between the second-type semiconductor conduction region 30 and the first-type semiconductor substrate 10. However, the area of the p-n junction 302 is much smaller than the area of the p-n junction 202. Thereby, the junction capacitance contacted by the external circuit is still controlled within a smaller range.

To be clearer, please refer to FIG. 1C, which shows a band diagram of the optoelectronic semiconductor structure according to the first embodiment of the present invention. The horizontal axis is the cut plane A-A′ in FIG. 1B; the vertical axis is the energy distribution (eV) of the cut plane A-A′. Under the influence of the semiconductor type, both the built-in electric fields of the second-type semiconductor conduction region 30 and the second-type semiconductor light-receiving region 20 will be smaller than that of the first-type semiconductor substrate 10. By making the concentrations of ions implanted into the second-type semiconductor conduction region 30 and the second-type semiconductor light-receiving region 20 different or by applying bias, the built-in electric field of the second-type semiconductor conduction region 30 will be smaller than that of the second-type semiconductor light-receiving region 20. By using the relation among the three, after the energy of the second-type semiconductor light-receiving region 20 is changed by accumulating photoelectrons e to some extent by illuminating the optoelectronic semiconductor structure 1 using the light source L, the energy barrier of the first-type semiconductor substrate 10 can be surmounted so that the second-type semiconductor conduction region 30 can collect the photoelectrons e at the p-n junction 202 via the first-type semiconductor substrate 10. In addition, by using the distance D (approximately equal to the distance between the p-n junction 202 and the other p-n junction 302) between the second-type semiconductor conduction region 30 will be smaller than that of the second-type semiconductor light-receiving region 20, the second-type semiconductor conduction region 30 coupled to the external circuit can be separated from the p-n junction 202 for extending the area of light receiving as well as separating the second-type semiconductor conduction region 30 from junction capacitance of the p-n junction 202.

The first embodiment of the present invention can be applied to the situation when the first-type semiconductor is an n-type semiconductor and the second-type semiconductor is a p-type semiconductor. Please refer to FIG. 1D, which shows a schematic diagram of another current flow in the optoelectronic semiconductor structure according to the first embodiment of the present invention. Since the semiconductor types are opposite, when the first-type semiconductor substrate 10 is an n-type semiconductor N, the second-type semiconductor light-receiving region 20 is a p-type semiconductor P1; and the second-type semiconductor conduction region 30 is a p-type semiconductor P2. After the light source L illuminates the optoelectronic semiconductor structure 1, the second-type semiconductor conduction region 30 can collect the holes at the p-n junction 202 via the first-type semiconductor substrate 10 and forming a photocurrent I. Likewise, the photoelectrons will be moved in the direction opposite to the direction of the holes. According to the general convention, the photocurrent I is positive. Accordingly, even in the situation when the first-type semiconductor is an n-type semiconductor and the second-type semiconductor is a p-type semiconductor, the operation principle and characteristics are roughly the same. According to the subsequent embodiments of the present invention, the first-type semiconductor being a p-type semiconductor and the second-type semiconductor being an n-type semiconductor are taken as an example for description.

According to the first embodiment of the present invention, by surrounding the second-type semiconductor conduction region 30 using the second-type semiconductor light-receiving region 20 and spacing the second-type semiconductor conduction region 30 and the second-type semiconductor light-receiving region 20 by a distance D, the light-receiving region (including the p-n junction 202) and the conduction region (including the second-type semiconductor conduction region 30) of the optoelectronic semiconductor structure 1 can be differentiated and the problem of a large junction capacitance due to enlarging the p-n junction according to the prior art can be solved. In other words, by using a properly designed distance D, the capacitance of the p-n junction 202 can be separated from the capacitance of the other p-n junction 302 for facilitating enlarging the area of the light-receiving region while controlling the junction capacitance contacted by the external circuit within a smaller range. Thereby, the subsequent problems, including circuit response delay and noise amplification, owing to the junction capacitance can be reduced.

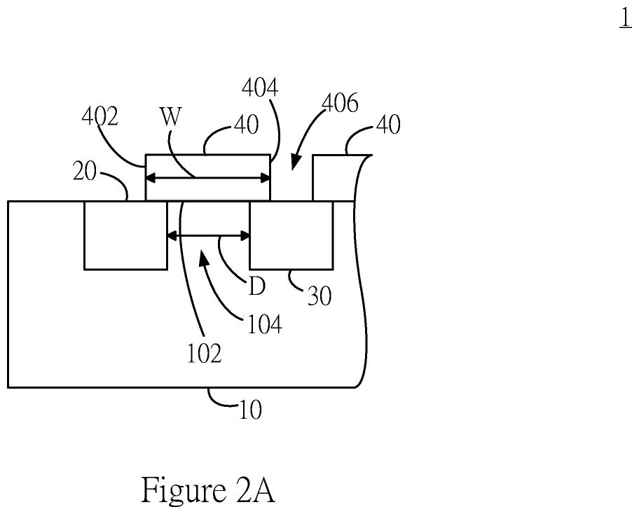

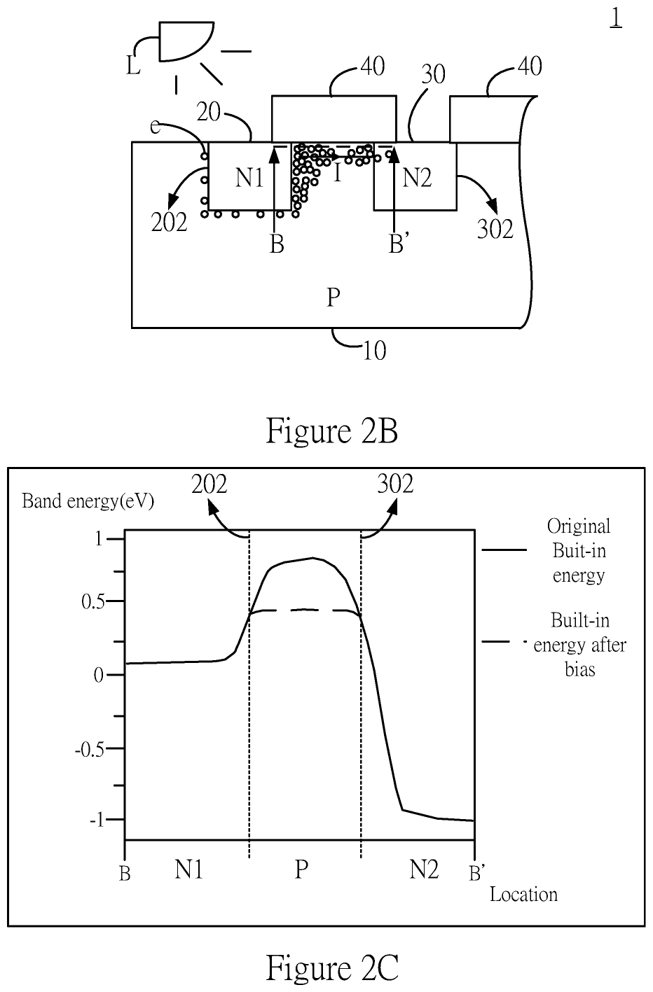

According to the first embodiment as described above, the distance D should be designed properly, for example, preferably 0.5 μm to 5 μm. This is because once the distance D is too large, it will be difficult for the second-type semiconductor conduction region 30 to collect photoelectrons from the second-type semiconductor light-receiving region 20. Contrarily, once the distance D is too short, the second-type semiconductor conduction region 30 and the second-type semiconductor light-receiving region 20 are equivalently connected. Consequently, the external circuit will contact the capacitance of the p-n junction 202 and face the problems according to the prior art. Thereby, according to the embodiment, there are some restrictions in layout design. Please refer to FIG. 2A, which shows a cross-sectional view of the optoelectronic semiconductor structure according to the second embodiment of the present invention. Based on the first embodiment of the present invention, the second embodiment according to the present invention further comprises a bias gate layer 40.

The bias gate layer 40 covers the top surface 102 of the first-type semiconductor substrate 10 and disposed between the second-type semiconductor light-receiving region 20 and the second-type semiconductor conduction region 30. A first side 402 of the bias gate layer 40 faces the second-type semiconductor light-receiving region 20. A second side 404 of the bias gate layer 40 faces the second-type semiconductor conduction region 30. The first side 402 and the second side 404 are separated by a width W, which can be greater than, equal to, or smaller than the distance D. When the width W is greater than the distance D, the first side 402 of the bias gate layer 40 can be located on the second-type semiconductor light-receiving region 20 and the second side 404 of the bias gate layer 40 can be located on the second-type semiconductor conduction region 30. When the width W is equal to or smaller than the distance D, the bias gate layer 40 can be only disposed on the top surface 102 of the first-type semiconductor substrate 10. The second side 404 of the bias gate layer 40 can include an opening 406 so that the second-type semiconductor conduction region 30 can be connected electrically to other components such as the external circuit through the contacts or vias.

According to FIG. 1C and the previous description, it is known that when the photocurrent I flow through the spacer part 104 of the first-type semiconductor substrate 10, it should surmount the energy barrier. Once the distance D is too large, the transport of photoelectrons will be obstructed. To increase the transport efficiency of photoelectrons, a larger distance D between the second-type semiconductor conduction region 30 and the second-type semiconductor light-receiving region 20 can be designed. According to the second embodiment of the present invention, by introducing the boas gate layer 40 between the second-type semiconductor light-receiving region 20 and the second-type semiconductor conduction region 30 and by applying a bias on the bias gate layer 40 to form a conduction channel in the first-type semiconductor substrate 10, the energy barrier caused by the spacer part 104 can be lowered.

Please refer to FIG. 2B, which shows a schematic diagram of current flow in the optoelectronic semiconductor structure according to the second embodiment of the present invention. When the first-type semiconductor substrate 10 is a p-type semiconductor, the second-type semiconductor light-receiving region 20 and the second-type semiconductor conduction region 30 ate n-type semiconductors N1, N2. There is a p-n junction 202 between the second-type semiconductor light-receiving region 20 and the first-type semiconductor substrate 10. When the light illuminates, since the photon energy can generate additional electrons and holes, the photocurrent I will be formed among the p-n junction 202, the first-type semiconductor substrate 10, and the second-type semiconductor conduction region 30. At this moment, by applying a bias at the bias gate layer 40, the energy barrier given by the first-type semiconductor substrate 10 can be suppressed so that it is easy for the second-type semiconductor conduction region 30 to collect the photoelectrons from the second-type semiconductor light-receiving region 20. The boas gate layer 40 can be fabricated by polysilicon.

Thereby, it is easy to connect the bias gate layer 40 using the metal layer and apply the bias thereto.

To elaborate, please refer to FIG. 2C, which shows a band diagram of the optoelectronic semiconductor structure according to the second embodiment of the present invention. The horizontal axis is the cut plane B-B′ in FIG. 2B; the vertical axis is the energy distribution (eV) of the cut plane B-B′. Just like the first embodiment, both the built-in electric fields of the second-type semiconductor conduction region 30 and the second-type semiconductor light-receiving region 20 will be smaller than that of the first-type semiconductor substrate 10 and thus forming an energy barrier in the first-type semiconductor substrate 10. Thanks to the addition of the bias gate layer 40, the bias gate layer 40 can provide a bias to suppress the energy barrier given by the first-type semiconductor substrate 10. Thereby, the photoelectrons can be easily collected by the second-type semiconductor conduction region 30, instead of imposing many limitations on the distance D. According to the above embodiments, the second-type semiconductor light-receiving region 20, the second-type semiconductor conduction region 30, and the bias gate layer 40 form an NMOS-like structure. The bias of the bias gate layer 40 is preferably between 0 and 1V. The applied bias can be adjusted according to the required magnitude of the photocurrent I and the distance D. By using the bias gate layer 40 to lower the energy barrier, the distance D can be further extended, which improves process flexibility as well as further lowering the junction capacitance contacted by the external circuit.

As described above, the second embodiment of the present invention can also be applied to the situation when the first-type semiconductor is an n-type semiconductor and the second-type semiconductor is a p-type semiconductor. Nonetheless, since the semiconductor types are opposite, the second-type semiconductor light-receiving region 20, the second-type semiconductor conduction region 30, and the bias gate layer 40 form a PMOS-like structure. The bias of the bias gate layer 40 is preferably between 0 and −1V. Likewise, the applied bias can be adjusted according to the required magnitude of the photocurrent I and the distance D.

According to the second embodiment of the present invention, by disposed the bias gate layer 40 on the spacer part 104 of the first-type semiconductor substrate 10, the energy barrier of the first-type semiconductor substrate 10 can be suppressed by further adjusting the bias for facilitating flow of the photocurrent. Thereby, the distance D can be further extended to increase process flexibility and lowering the junction capacitance contacted by the external circuit.

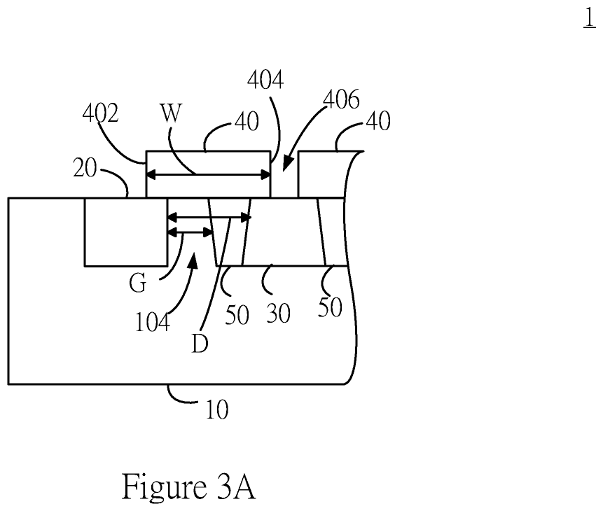

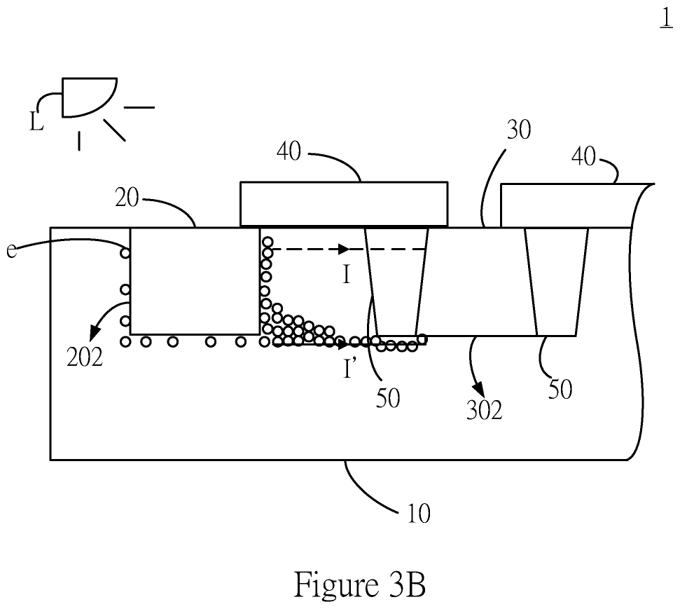

As described above, according to the second embodiment, the gate bias applied to the bias gate layer 40 should be adjusted properly. If the bias is too high, the external circuit will contact a portion of the capacitance of the p-n junction 202. Contrarily, if the bias is too low, the effect of suppressing the energy barrier given by the first-type semiconductor substrate 10 will be inferior. Designing the bias properly can be done by a person having ordinary skills in the art. Nonetheless, to further lower the design difficulty for the optoelectronic semiconductor structure, please refer to FIG. 3A, which shows a cross-sectional view of the optoelectronic semiconductor structure according to the third embodiment of the present invention. The difference between the third embodiment and the second embodiment is an isolation layer 50 further disposed in the third embodiment, as described in detail below.

The isolation layer 50 is disposed on the outer side of the second-type semiconductor conduction region 30 and on the top surface 102 of the first-type semiconductor substrate 10. The isolation layer 50 and the second-type semiconductor light-receiving region 20 are spaced by a gap G for reserving the conduction channel formed in the first-type semiconductor substrate 10 when the bias gate layer 40 is biased. The isolation layer 50 can be a shallow trench isolation (STI). According to the STI technology, the first-type semiconductor substrate 10 is etched to form trenches between the first-type semiconductor substrate 10 and the second-type semiconductor conduction region 30. Finally, isolation materials are filled into the trenches to form the isolation layer 50 for isolating devices. The material of the isolation layer 50 can be selected from the group consisting of silicon nitride (Si3N4), silicon carbide (SiC), and silicon dioxide (SiO2). The width of the isolation layer 50 is preferably 0.5 μm to 5 μm. The depth is determined by the STI process.

Please refer to FIG. 3B, which shows a schematic diagram of current flow in the optoelectronic semiconductor structure according to the third embodiment of the present invention. When the first-type semiconductor substrate 10 is a p-type semiconductor, the second-type semiconductor light-receiving region 20 and the second-type semiconductor conduction region 30 ate n-type semiconductors N1, N2. There is a p-n junction 202 between the second-type semiconductor light-receiving region 20 and the first-type semiconductor substrate 10. When the light illuminates, since the photon energy can generate additional electrons and holes, the photocurrent I′ will be formed among the p-n junction 202, the first-type semiconductor substrate 10, and the second-type semiconductor conduction region 30. Compared to the previous embodiment, in which the photocurrent I can reach the second-type semiconductor conduction region 30 directly via the p-n junction 302 between the second-type semiconductor conduction region 30 and the first-type semiconductor substrate 10, since there is the isolation layer 50 in the present embodiment, the photocurrent I′ needs to pass a very short diffusion distance (equivalent to the width of the isolation layer 50) for detouring the isolation layer 50 before reaching the second-type semiconductor conduction region 30. Consequently, the external circuit is blocked from contacting the capacitance of the p-n junction 202 via the other p-n junction 302, and then the design difficulty for the gate bias of the bias gate layer 40 can be reduced.

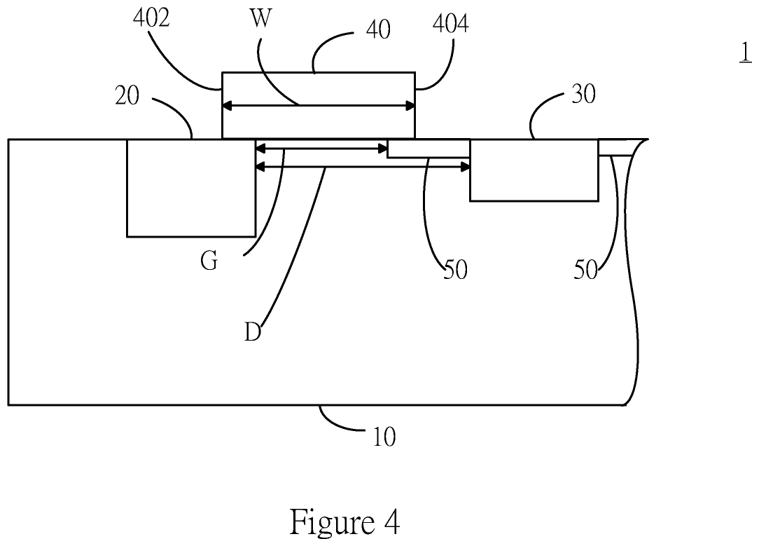

Furthermore, please refer to FIG. 4, which shows a cross-sectional view of the ease optoelectronic semiconductor structure according to the fourth embodiment of the present invention. The difference between the fourth embodiment and the third one is that the isolation layer 50 according to the fourth embodiment can be a first-type semiconductor layer. The concentration of ions implanted into the first-type semiconductor layer is higher than into the first-type semiconductor substrate 10. For example, when the first-type semiconductor substrate 10 is a p-type semiconductor substrate, the first-type semiconductor layer can be a p-type semiconductor region with high doping concentration or another material with implantation concentration higher than the p-type semiconductor substrate. Thereby, because the built-in electric field of the first-type semiconductor layer is higher than the first-type semiconductor substrate 10, it is difficult for the photoelectrons to directly cross the isolation region 50 and reach the second-type semiconductor conduction region 30. Then the similar isolation effect can be achieved. By blocking the external circuit from contacting the capacitance of the p-n junction 202 via the other p-n junction 302, the design difficulty for the gate bias of the bias gate layer 40 can be reduced as well.

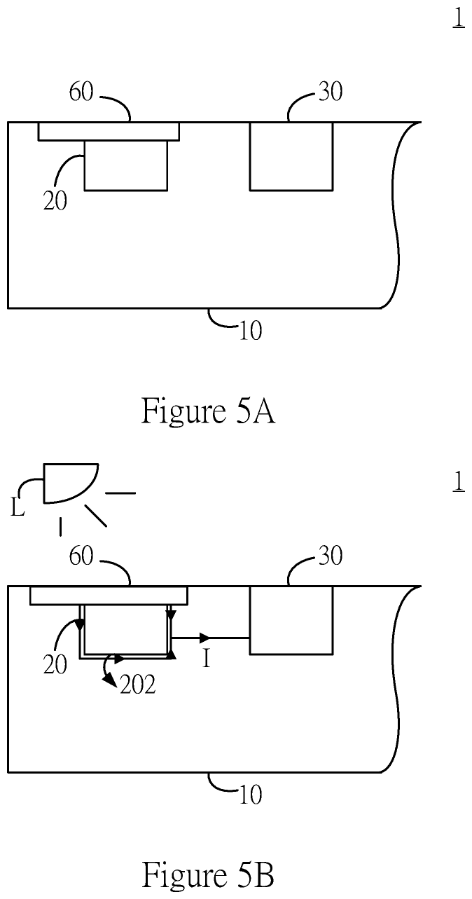

In general, there still exists a dark current in an optoelectronic semiconductor structure in no light illumination. The dark current is partially caused by surface defects. To reduce the influence of the dark current component on the photocurrent I, please refer to FIG. 5A, which shows a cross-sectional view of the optoelectronic semiconductor structure according to the fifth embodiment of the present invention. Based on the first embodiment of the present invention, the fifth embodiment according to the present invention further comprises a first-type semiconductor shelter layer 60 disposed on the second-type semiconductor light-receiving region 20. For example, after forming the second-type semiconductor light-receiving region 20 on the top surface 102 of the first-type semiconductor substrate 10 by selectively diffusion (using a mask or other lithography technologies), the first-type semiconductor shelter layer 60 can be further fabricated on the top surface 102 of the first-type semiconductor substrate 10. As shown in the figure, the first-type semiconductor shelter layer 60 can cover the second-type semiconductor light-receiving region 20 completely. Alternatively, as will be shown in the subsequent embodiment, only a portion of the first-type semiconductor shelter layer 60 covers the second-type semiconductor light-receiving region 20. The first-type semiconductor shelter layer 60 allows light penetration. Thereby, the function of the second-type semiconductor light-receiving region 20 in receiving the incident light is not influenced.

Please refer to FIG. 5B, which shows a schematic diagram of current flow in the optoelectronic semiconductor structure according to the fifth embodiment of the present invention. The first-type semiconductor shelter layer 60 can cover or partially cover the second-type semiconductor light-receiving region 20 from the top surface 102 of the first-type semiconductor substrate 10. Thereby, the dark current formed by surface defects can be avoided and thus reducing its influence on the photocurrent I.

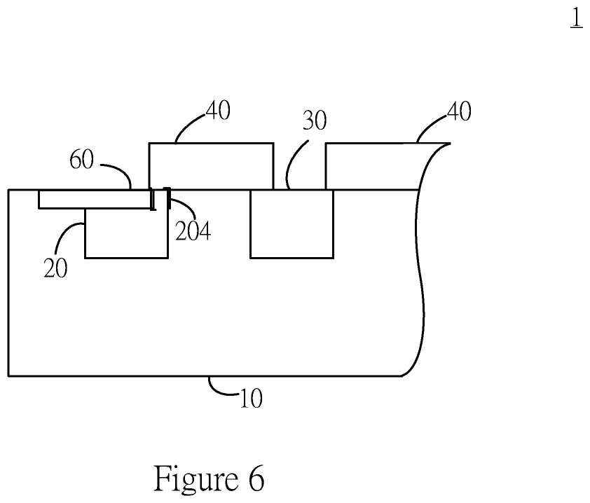

Please refer to FIG. 6, which shows a cross-sectional view of the optoelectronic semiconductor structure according to the sixth embodiment of the present invention. Based on the second embodiment of the present invention, likewise, the sixth embodiment of the present invention includes a first-type semiconductor shelter layer 60 on the second-type semiconductor light-receiving region 20. When the bias gate layer 40 is present, the first-type semiconductor shelter layer 60 does not cover an end part 204 of the semiconductor light-receiving region 20 facing the bias gate layer 40 for avoiding the first-type semiconductor shelter layer 60 from too proximate to the bias gate layer 40. The proximity will induce an energy barrier for the transport of the photocurrent I.

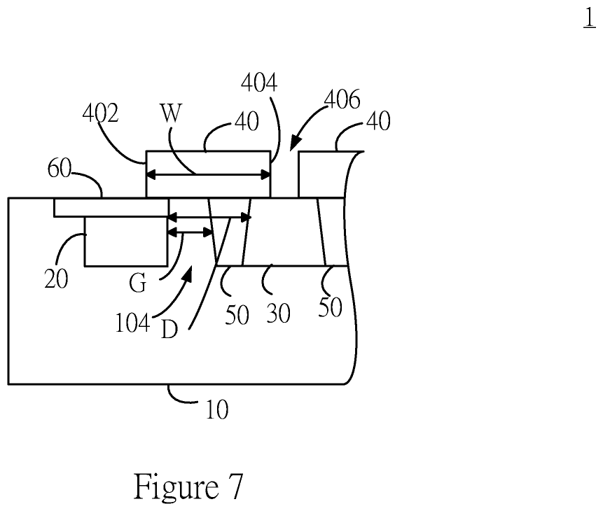

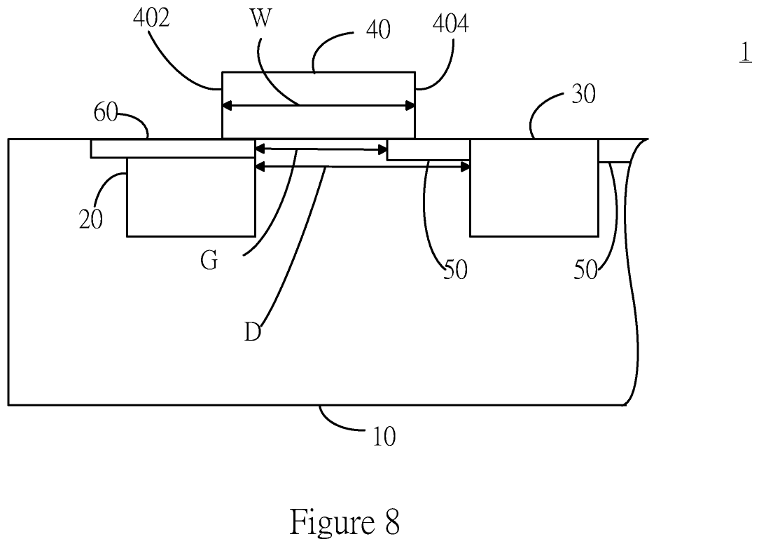

Please refer to FIG. 7 shows a cross-sectional view of the optoelectronic semiconductor structure according to the seventh embodiment of the present invention. Based on the third embodiment of the present invention, a first-type semiconductor shelter layer 60 is disposed on the second-type semiconductor light-receiving region 20. Please refer to FIG. 8, which shows a cross-sectional view of the optoelectronic semiconductor structure according to the eighth embodiment of the present invention. Based on the fourth embodiment of the present invention, a first-type semiconductor shelter layer 60 is disposed on the second-type semiconductor light-receiving region 20.

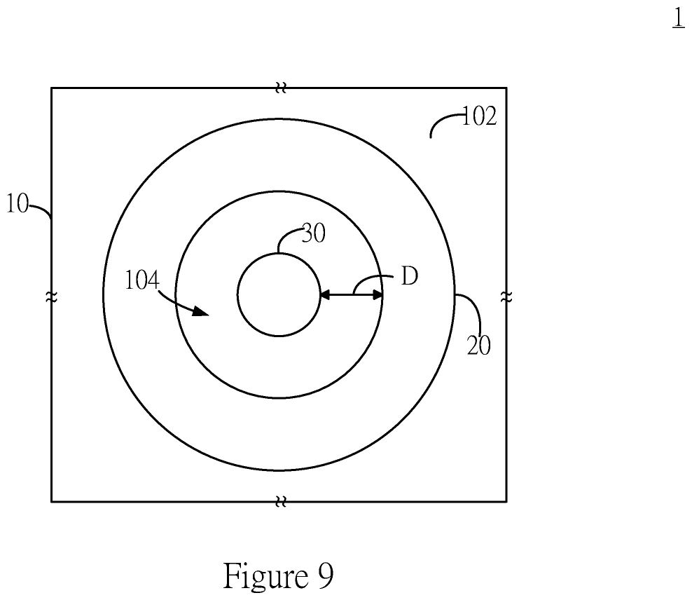

In the various embodiments of the optoelectronic structure according to the present invention, to increase the photocurrent I for enhancing the sensitivity in light sensing, the light-receiving region should be enlarged. Please refer to FIG. 9 shows a top view of the optoelectronic semiconductor structure according to the ninth embodiment of the present invention. The second-type semiconductor light-receiving region 20 completely surrounds the second-type semiconductor conduction region 30. Thereby, while doing layout, it is easy to make the second-type semiconductor light-receiving region 20 have a larger light-receiving area by simply extending outwards to the range of the second-type semiconductor light-receiving region 20. As described above, alternatively, the second-type semiconductor light-receiving region 20 can partially surround the second-type semiconductor conduction region 30. Besides, the shapes of the second-type semiconductor light-receiving region 20 and the second-type semiconductor conduction region 30 are not limited to the circles shown in the present embodiment. In practice, they can be various shapes such as ellipses or polygons, as determined by the spatial arrangement of the circuit.

Moreover, to make the junction capacitance contacted by the external circuit smaller, it is expected that the condition region in the optoelectronic semiconductor structure according to the embodiments of the present invention can be shrunk. In addition to reducing the range of the second-type semiconductor conduction region 30 in the direction parallel with the top surface 102, as described the previous embodiment, the second-type semiconductor light-receiving region 20 can be a second-type semiconductor well and the second-type semiconductor conduction region 30 can be a second-type semiconductor with high doping concentration. Because the depth of the semiconductor well is normally greater than the semiconductor highly doped region, a shallow second-type semiconductor conduction region 30 can also make the junction capacitance between the second-type semiconductor conduction region 30 and the first-type semiconductor substrate 10 smaller.

Furthermore, in applications, the second-type semiconductor conduction region 30 can be coupled to an analog-to-digital converter. The details will be described as follows.

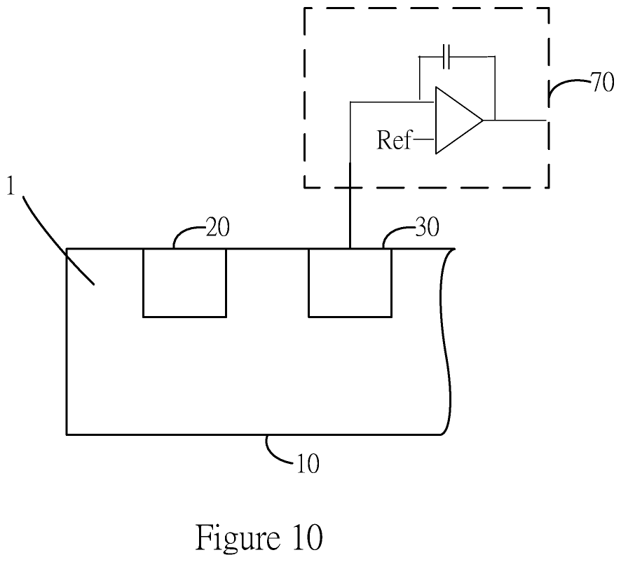

Please refer to FIG. 10, which shows a schematic diagram of the circuit architecture of the optoelectronic semiconductor structure according to the tenth embodiment of the present invention. The optoelectronic semiconductor structure 1 according to the present invention is further coupled to an analog-to-digital converter 70. To elaborate, the second-type semiconductor conduction region 30 can be coupled to the analog-to-digital converter 70 through one or more contact or via in the metal layer. The analog-to-digital converter 70 normally includes an integration circuit formed by amplifiers. Because the photocurrent generated by the optoelectronic semiconductor structure 1 is an analog signal. The subsequent circuit generally needs to convert the analog signal to a digital signal before the value of the photocurrent can be processed and the intensity of the incident light can be judged.

To sum up, the embodiments of the present invention provide several improved optoelectronic semiconductor structures. By dividing the first-type semiconductor substrate into a semiconductor conduction region and a light-receiving region, the unavoidable problem of increased junction capacitance when the area of the p-n junction in an optoelectronic semiconductor structure is enlarged can be solved. When the area of the light-receiving region is enlarged, the junction capacitance contacted by the external circuit can be controlled within a smaller range. Thereby, the subsequent problems, including circuit response delay and noise amplification, owing to the junction capacitance can be reduced, achieving the effect of reducing the junction capacitance while maintaining the light-receiving capability. In addition, according to different embodiments of the present invention, a bias device can be adopted to enhance the photoelectric conversion efficiency of optoelectronic semiconductor structures; an isolation layer can be used to avoid the external circuit from contacting the junction capacitance of the light-receiving region; or a shelter layer is used to reduce the dark current caused by surface defects. All these methods can further improve the technical effects of the present invention.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. An optoelectronic semiconductor structure, comprising:
a first-type semiconductor substrate, having a top surface;
a second-type semiconductor light-receiving region; and
a second-type semiconductor conduction region, disposed on said top surface of said first-type semiconductor substrate, used for conducting a photocurrent, said second-type semiconductor light-receiving region surrounding said second-type semiconductor conduction region, and said second-type semiconductor conduction region and said second-type semiconductor light-receiving region spaced by a distance.

2. The optoelectronic semiconductor structure of claim 1, wherein said second-type semiconductor light-receiving region surrounds or partially surrounds said second-type semiconductor conduction region.

3. The optoelectronic semiconductor structure of claim 1, wherein said first-type semiconductor substrate includes a spacer part; the inner side of said spacer part surrounds or partially surrounds said second-type semiconductor conduction region; and the outer side of said spacer part is adjacent to said second-type semiconductor light-receiving region.

4. The optoelectronic semiconductor structure of claim 1, and further comprising a bias gate layer, covering said top surface of said first-type semiconductor substrate, and located between said second-type semiconductor light-receiving region and said second-type semiconductor conduction region.

5. The optoelectronic semiconductor structure of claim 4, wherein a first side of said bias gate layer is disposed on said second-type semiconductor light-receiving region, and a second side of said bias gate layer is disposed on said second-type semiconductor conduction region.

6. The optoelectronic semiconductor structure of claim 4, and further comprising an isolation layer, disposed on the outer side of said second-type semiconductor conduction region and on said top surface of said first-type semiconductor substrate, and spaced by said second-type semiconductor light-receiving region by a gap.

7. The optoelectronic semiconductor structure of claim 6, wherein said isolation layer is a shallow trench isolation (STI) with material selected from the group consisting of silicon nitride (Si3N4), silicon carbide (SiC), and silicon dioxide (SiO2).

8. The optoelectronic semiconductor structure of claim 6, wherein said isolation layer is a first-type semiconductor layer with the concentration of implanted ions higher than the concentration of ions implanted into said first-type semiconductor substrate.

9. The optoelectronic semiconductor structure of claim 1, wherein said second-type semiconductor light-receiving region is disposed on said top surface of said first-type semiconductor substrate.

10. The optoelectronic semiconductor structure of claim 1, and further comprising a first-type semiconductor shelter layer, disposed on said second-type semiconductor light-receiving region and said top surface of said first-type semiconductor substrate.

11. The optoelectronic semiconductor structure of claim 4, and further comprising a first-type semiconductor shelter layer, disposed on said second-type semiconductor light-receiving region and said top surface of said first-type semiconductor substrate.

12. The optoelectronic semiconductor structure of claim 11, wherein said first-type semiconductor shelter layer does not cover an end part of said second-type semiconductor light-receiving region facing said bias gate layer.

13. The optoelectronic semiconductor structure of claim 4, wherein said bias gate layer is polysilicon.

14. The optoelectronic semiconductor structure of claim 1, wherein said second-type semiconductor conduction region is coupled to an analog-to-digital converter.

15. The optoelectronic semiconductor structure of claim 1, wherein said second-type semiconductor light-receiving region is a second-type semiconductor well, and said second-type semiconductor conduction region is a second-type semiconductor with high doping concentration.

16. The optoelectronic semiconductor structure of claim 1, wherein the concentration of ions implanted into said second-type semiconductor conduction region is higher than the concentration of ions implanted into said second-type semiconductor light-receiving region.

17. The optoelectronic semiconductor structure of claim 1, wherein when said first-type semiconductor substrate is p-type, said photocurrent includes the photoelectrons flowing from said second-type semiconductor light-receiving region to said second-type semiconductor conduction region via said first-type semiconductor substrate.

18. The optoelectronic semiconductor structure of claim 1, wherein when said first-type semiconductor substrate is n-type, said photocurrent includes the holes flowing from said second-type semiconductor light-receiving region to said second-type semiconductor conduction region via said first-type semiconductor substrate.
